(19) United States
(12) Patent Application Publication
(10) Pub. No.: US 2004/0028810 A1
(43) Pub. Date: Feb. 12, 2004

(54) Chemical vapor deposition reactor and method for utilizing vapor vortex

(75) Inventors: Robert W. Grant, Hershey, PA (US); Benjamin J. Petrone, Mt. Bethel, PA (US); Matthew D. Brubaker, Colorado Springs, CO (US); Paul D. Mumbauer, Mohrsville, PA (US)

Correspondence Address: PATTON BOGGS, PO BOX 270930, LOUISVILLE, CO, 80027, US

(73) Assignee: Primaxx, Inc., Allentown, PA (US)

(21) Appl. No.: 10/310,474

(22) Filed: Dec. 4, 2002

Related U.S. Application Data
(63) Continuation-in-part of application No. 10/214,272, filed on Aug. 6, 2002, now abandoned.
Application No. 10/214,272 is a division of application No. 09/688,555, filed on Oct. 16, 2000, now Pat. No. 6,428,847.
(60) Provisional application No. 60/337,639, filed on Dec. 4, 2001.

(51) Int. Cl. C23C 16/00

(52) U.S. Cl. 427/248.1; 118/715

(57) ABSTRACT

A chemical vapor deposition (CVD) reactor comprising: a reactor chamber; a substrate holder located within the reactor chamber; a gas inlet system arranged to provide a gas flow rotating above the substrate holder; and a gas exhaust. The flow characteristics of the precursor gas are controlled to equalize the thin film thickness across the substrate surface by forcing the gas into a smaller volume as it moves across the substrate. With a central exhaust, this is done by reducing the height of the reactor chamber with increasing proximity to the center of the reactor chamber so that the reactor volume per unit distance decreases as the gas moves from the inlet to the exhaust.

### RELATED APPLICATIONS

The instant application is a continuation-in-part of U.S. patent application Ser. No. 10/214,272 filed Aug. 6, 2002, which is a divisional application of U.S. patent application Ser. No. 09/688,555 filed Oct. 16, 2000, which matured into issued U.S. Pat. No. 6,428,847. The instant application also claims the benefit of U.S. Provisional Application Serial No. 60/337,639 filed Dec. 4, 2001 by Robert W. Grant, entitled “Process And Apparatus For Chemical Vapor Deposition (CVD)”. The instant application is related to concurrently filed, co-pending, and commonly assigned U.S. Patent Application Serial No. 13180.114US, entitled “CHEMICAL VAPOR DEPOSITION VAPORIZER”, the disclosure of which application is hereby incorporated herein by reference.

### BACKGROUND OF THE INVENTION

1. Field of the Invention

The present invention relates in general to a chemical vapor deposition (CVD) reactor and in particular to a CVD reactor providing desired vapor phase stoichiometry and effective substrate coverage.

2. Statement of the Problem

CVD is a common method of depositing thin films of complex compounds, such as metal oxides, ferroelectrics, superconductors, materials with high dielectric constants, gems, etc. Existing methods of chemical vapor deposition, while providing good step coverage, generally result in relatively low integrated circuit yields when used to deposit the complex materials. In prior art CVD methods, one or more liquid or solid precursors are converted into a gaseous state. To gasify sufficient quantities of precursor at a commercially viable rate, it is typically necessary to heat the precursor. However, the precursors are typically physically unstable at the higher temperatures necessary to achieve sufficient mass transfer of the precursor from the liquid phase or solid phase to the gaseous phase. This physical instability may manifest itself in premature boiling of the precursor solvents. Consequently, precursor compounds commonly experience separation, decomposition, or precipitation. Premature separation causes undesirable, uncontrolled changes in the chemical stoichiometry of the process streams and the final product, uneven deposition of the substrate in the CVD reactor, and fouling of the CVD apparatus, necessitating costly and highly inconvenient disruptions of CVD equipment operation to clean affected equipment components. Further, particulate matter can fall down onto the wafer resulting in defective devices and low yields. In addition, because premature separation of precursor reagents generally does not occur uniformly for all components of a precursor, it also results in a disproportionate removal of selected reagents from a gas precursor causing the remaining gas precursor to include an altered stoichiometry which results in ineffective chemical compositions on the surface of the wafer.

Another problem with existing CVD systems is that of incomplete gasification of precursors. Where one or more precursors fail to properly gasify in apparati leading to the deposition chamber, the one or more precursors may be deposited on a substrate without having properly reacted with other precursors in the CVD apparatus. This is due to the growth of interdependency between certain precursors. Such improper deposition causes waste of the unreacted precursor materials and may cause malfunction of the circuit onto which such deposition takes place.

One existing approach for wafer processing involves the use of CVD reactors with showerhead gas dispensers located over a heated rotating substrate. The substrate is generally rotated to provide a substantially uniform boundary layer under the free flowing gas providing substantially uniform reagent concentration over the substrate. The showerhead has been successful in high temperature processes; however, problems arise when using the showerhead design in conjunction with the deposition of heavier molecules, such as those used in the formation of strontium bismuth titanate (SBT) and other layered superlattice materials. The layered superlattice material precursors typically have low vapor pressures and correspondingly high vaporization temperatures. However, the layered superlattice material precursors also typically have low decomposition temperatures, thereby imposing demanding constraints upon the required ambient temperature range needed for a CVD reactor. High vaporization temperatures typically cause premature decomposition of the layered superlattice material precursor leading to the problems summarized above. If the temperature is lowered to avoid these problems, incomplete gasification can occur, due to solvent boil-off and precipitation.

One existing approach involves the use of a modified heavy molecule precursor in combination with existing CVD apparati. The theory is that a precursor, modified to exhibit high component vapor pressures, would remove the need for high vaporization temperatures in the CVD process and thereby avoid the problems of precipitation and premature decomposition. However, the precursor obtained, although having a high vapor pressure, had poor characteristics for growing layers on a wafer, one of which characteristics was a poor sticking coefficient.

Accordingly, there is a need in the art for a CVD system and method capable of reliably depositing SBT and other heavy or complex molecules onto wafers which does not incur the problems of premature decomposition and incomplete gasification.

### Solution

The present invention advances the art and helps to overcome the aforementioned problems by introducing a precursor gas into a reactor chamber, circulating the precursor gas above a substrate, and growing a layer of material on the surface of the substrate at a substantially uniform rate over the surface of the substrate. The shape of the reactor plays a key role. In the preferred embodiment, the shape is such that the precursor gas is forced into a smaller volume as the gas is depleted.

In one embodiment, a CVD reactor is provided which enables a flow of gas precursors which may include SBT and/or other metal oxide molecules over a wafer, which gas flow has a controlled boundary layer thickness and which enables a substantially constant rate of material growth over the surface of the wafer. The described deposition preferably occurs without causing premature decomposition of, and precipitation of particulate matter from, the gas precursor(s) flowing over the wafer or substrate. While the foregoing discussion describes the suitability of the CVD reactor for use with precursors that include SBT and other metal oxide molecules, it will be appreciated that the CVD reactor disclosed herein may be employed with a wide range of precursors and reagents, including silicon.

In one embodiment, precursor gas is introduced into a CVD reactor at a perimeter of the reactor chamber and in a direction substantially tangential to the chamber circumference, thereby generating a spinning field of precursor gas over a preferably stationary substrate. This approach removes a need for the showerhead dispenser of existing CVD systems and the problem of particulate matter buildup attendant thereto. The use of a stationary substrate benefits the reactor design by eliminating the need for equipment for rotating the substrate and by enabling easier measurement of the substrate temperature. In the prior art, such temperature measurement was complicated by the need to measure temperature with a pyrometer, by using telemetry, or by running temperature measurement leads out of rotating equipment.

In one embodiment, one or more tubes direct precursor gas into a conduit located about the circumference of a reactor chamber. Preferably, one or more channels emerging from the circumferential conduit direct the precursor gas into the reactor chamber along a direction substantially tangential to the circumference of the reactor chamber. Preferably, an inlet is located at the chamber end of each channel. An opening is preferably located substantially at the center of the reactor chamber to exhaust the precursor gas. This approach preferably provides a uniform gas flow along the inside circumference of the reactor. In one embodiment, the height of the reactor chamber containing the precursor gas flow is reduced substantially proportionately with diminishing radial distance from the center of the reactor gas flow. Thus, two factors tend to increase gas flow velocity toward the center of the reactor chamber. First, the conservation of angular momentum demands that the gas linear velocity increase as radial distance of gas flow from the chamber center decreases. Second, the diminishing chamber height diminishes the cross-sectional area of gas flow toward the chamber center, thereby requiring an increase in linear gas flow velocity to maintain a constant mass flow rate. Preferably, the increase in gas flow velocity leads to a reduced flow boundary layer thickness toward the chamber center, which in turn leads to an increased total exposure of reagents to the substrate toward the chamber center, via gas diffusion. Preferably, this increased exposure of reagents with diminishing radial distance compensates for increasing depletion of precursor gas reagents occurring as the precursor gas flows over the substrate toward the center. Preferably, accurate compensation of reagent depletion with increased reagent diffusion enables a substantially uniform film growth rate over the substrate surface. While the above discussion is directed primarily to a reactor chamber which is circular in the horizontal plane, the reactor chamber is not limited to circular or horizontal geometries and may assume a wide range of shapes and/or attitudes.

The invention provides a chemical vapor deposition method comprising: providing a reactor chamber including a substrate defining a substrate plane; moving a precursor gas through the chamber in a direction from a gas inlet to an exhaust port and in a circular motion about an axis substantially perpendicular to the substrate plane while reducing the reactor volume per unit distance available to the precursor gas as the precursor gas moves in the direction; and reacting the vapor to deposit a solid thin film on the surface of the substrate. Preferably, the moving comprises providing spiral motion. Preferably, the moving comprises increasing a velocity of the precursor gas with increasing proximity of the precursor gas to a center of the reactor chamber. Preferably, the moving comprises controlling flow characteristics of the moved precursor gas to compensate for depletion of reagents within the moved precursor gas. Preferably, the moving comprises controlling flow characteristics of the moved precursor gas to substantially equalize the film thickness across the substrate surface. Preferably, the moving comprises decreasing a boundary layer thickness of gas precursor flow over the substrate surface with increasing proximity to a center of the reactor chamber. Preferably, the moving comprises increasing a diffusion rate of reagents from the precursor gas to the substrate surface with increasing proximity to a center of the reactor chamber. Preferably, the providing a reactor chamber comprises providing a substantially circular reactor chamber and the direction is substantially radially inward. Preferably, the reducing comprises reducing a height of the reactor chamber with increasing proximity to the center of the reactor chamber. Preferably, the substrate is maintained substantially stationary. Preferably, the method further comprises maintaining a temperature of the reactor chamber below a decomposition temperature of the precursor gas. Preferably the method comprises maintaining comprises maintaining a temperature of sidewalls of the reactor chamber at substantially 200° C. Preferably, the maintaining comprises maintaining a temperature of the precursor gas at substantially 200° C. Preferably, the method further comprises maintaining a pressure within the reactor chamber below 10 Torr (133.3 Newtons per square meter). More preferably, the method comprises maintaining a pressure within the reactor chamber at substantially 1 Torr (133.3 Newtons per square meter). The method preferably further comprises maintaining a temperature of the substrate between 320° C. and 360° C. Most preferably the temperature of the substrate is maintained at a temperature of the substrate at substantially 340° C.

The invention also provides a chemical vapor deposition (CVD) reactor comprising: a reactor chamber; a substrate holder located within the reactor chamber; a gas inlet system including a gas inlet; and gas exhaust port; wherein the reactor chamber is shaped such that the reactor volume per unit distance decreases in a direction from the gas inlet to the gas exhaust port. Preferably, the reactor chamber includes a circular wall and the gas inlet system comprises a gas inlet directed substantially tangential to the circular wall. Preferably, the reactor chamber is substantially circular and the direction is radially inward. Preferably, the reactor includes a top wall, and wherein a height of the reactor chamber top wall above the substrate holder increases with increasing distance from a center of the chamber. Preferably, the height of the chamber top wall above the substrate holder varies substantially linearly with a distance from the center of the chamber. Preferably, the reactor includes a top wall, and wherein a height of the reactor chamber top wall above the substrate is a function of a reagent depletion rate in the chamber. Preferably, the reactor includes a top wall, and a height of the reactor chamber top wall above the substrate varies with radial position to compensate for a rate of reagent depletion during gas flow through the chamber. Preferably, the reactor includes a top wall, and the shape of the chamber is designed to provide substantially uniform film growth rate on a substrate located on the substrate holder. Preferably, the substrate holder is substantially fixed within the reactor so that it is substantially stationary. Preferably, the substrate holder comprises a heater. Preferably, the gas inlet system comprises a plurality of channels through the reactor chamber. Preferably, the channels are oriented substantially tangentially to a sidewall of the reactor chamber. Preferably, the inlet is at a periphery of the reactor chamber. Preferably, the gas inlet system, the reactor chamber, and the gas exhaust port cooperate to provide spiral gas flow from an internal perimeter of the chamber, over the substrate holder, to the gas exhaust port. Preferably the exhaust port is substantially centrally located in the reactor. Preferably, at the periphery of the chamber the top wall is 10 cm or less above the level of the substrate holder and near the exhaust port, and the top wall is 5 cm or less above the level of the substrate holder. Preferably, the chamber includes a top wall and at the periphery of the chamber the top wall is 5 cm or less above the level of the substrate holder and near the exhaust port, and the top wall is 2.5 cm or less above the level of the substrate holder.

Having thus described the above embodiments and set forth significant aspects and features thereof, it is the principal object of a preferred embodiment to provide a vortex-based CVD reactor that provides uniform deposition of a precursor on a substrate. The above and other advantages of the present invention may be better understood from a reading of the following description of the invention taken in conjunction with the drawings in which:

### BRIEF DESCRIPTION OF THE DRAWINGS

FIG. 1 is a perspective view of a vortex-based CVD reactor according to the invention;

FIG. 2 is a cross-section view of the vortex-based CVD reactor along line 2-2 of FIG. 1;

FIG. 3 is a top view of the base of the reactor of FIG. 1;

FIG. 4 is a perspective view of the reactor base of FIG. 3;

FIG. 5 is a cross-section view of the vortex-based CVD reactor of FIG. 1 showing a spinning gas field within the reactor interior;

FIG. 6 is a top view of the vortex-based CVD reactor of FIG. 1 showing the spinning gas field in the reactor interior;

FIG. 7 illustrates the flow of gas through the reactor of FIG. 1 as simulated by using the exact dimensions, gas type, and temperature;

FIG. 8 is a top view of the rotating gas field of FIG. 7 at the plane of the substrate, showing good homogeneity of the spiraling gas;

FIG. 9 is a side sectional view of a portion of a reactor according to the preferred embodiment of the present invention coupled to a vaporizer;

FIG. 10 is a side sectional view of a portion of the reactor of FIG. 9 showing a reactor housing;

FIG. 11 is a side sectional view of a portion of the reactor of FIG. 9 showing a primary exhaust connection;

FIG. 12 is a perspective view of a portion of the reactor of FIG. 9 showing a plurality of channels;

FIG. 13 is a close-up perspective view of a portion of a conduit forming part of the reactor of FIG. 9;

FIG. 14 is a front-end section view of a portion of a conduit of the reactor of FIG. 9; and

FIG. 15 is an expanded side sectional view of a portion of the reactor chamber shown in FIG. 9.

### DETAILED DESCRIPTION OF THE PREFERRED EMBODIMENT

The term “mist” as used herein is defined as fine droplets or particles of a liquid and/or solid carried by a gas. The term “mist” includes an aerosol, which is generally defined as a colloidal suspension of solid or liquid particles in a gas. The term “mist” also includes a fog, as well as other nebulized suspensions of the precursor solution in a gas. Since the above term and other terms that apply to suspensions in a gas have arisen from popular usage, the definitions are not precise, overlap, and may be used differently by different authors. In general, the term “aerosol” is intended to include all the suspensions included in the text “Aerosol Science and Technology”, by Parker C. Reist, McGraw-Hill, Inc., New York, 1983, which is incorporated by reference. The term “mist” as used herein is intended to be broader than the term “aerosol”, and includes suspensions that may not be included under the terms “aerosol” or “fog”. The term “mist” is to be distinguished from a gasified liquid, that is, a gas. It is an object of this invention to use a venturi to create a mist from a liquid precursor blend in which the resulting precursor mist droplets have an average diameter of less than one micron and preferably in the range of 0.2 microns-0.5 microns.

The terms “atomize” and “nebulize” are used interchangeably herein in their usual sense when applied to a liquid, which is to create a spray or mist, that is, to create a suspension of liquid droplets in a gas. The term “vapor” means a gas of a chemical species at a temperature below its critical temperature. The terms “vaporize”, “vaporization”, “gasify”, and “gasification” are used interchangeably in this specification.

In a typical CVD process, reagents necessary to form a desired material are usually prepared in liquid precursor solutions, the precursors are vaporized (i.e., gasified), and the gasified reagents are fed into a deposition reactor containing a substrate, where they decompose to form a thin film of desired material on the substrate. The reagent vapors can also be formed from gases, and from solids that are heated to form a vapor by sublimation.

The term “thin film” is used herein as it is used in the integrated circuit art. Thin film means a film of less than a micron in thickness. The thin films disclosed herein are in all instances less than 0.5 microns in thickness. Preferably, the films formed by the CVD apparatus described herein are less than 300 nm thick, and most preferably are less than 200 nm thick. Films of from 20 nm to 100 nm are routinely made by the devices according to the invention. These thin films of the integrated circuit art should not be confused with so-called thin coatings or films in so-called “thin-film capacitors”. While the word “thin” is used in describing such coatings and films, these are “thin” only in respect to macroscopic materials and are generally tens and even hundreds of microns thick. The non-uniformities in such “thin” coatings are much larger than the entire thickness of a thin film as used herein; thus, the processes by which such coatings and films are made are considered by those skilled in the integrated circuit art to be incompatible with the integrated circuit art.

In the literature, there is often some inconsistent use of such terms as “reagent”, “reactant”, and “precursor”. In this application, the term “reagent” will be used to refer generally to a chemical species or its derivative that reacts in the deposition reactor to form the desired thin film. Thus, in this application, reagent can mean, for example, a metal-containing compound contained in a precursor, a vapor of the compound, or an oxidant gas. The term “precursor” refers to a particular chemical formulation used in the CVD method that comprises a reagent. For example, a precursor may be a pure reagent in solid or liquid or gaseous form. Typically, a liquid precursor is a liquid solution of one or more reagents in a solvent. Precursors may be combined to form other precursors. Herein, the original precursors used to form such a combination are precursor components; and, generally, the resulting combination is a precursor blend. Precursor liquids generally include a metal compound in a solvent, such as metal-organic precursor formulations, including alkoxides, sometimes referred to as sol-gel formulations, carboxylates, sometimes referred to as MOD formulations, and alkoxycarboxylates, sometimes referred to as EMOD formulations, and other formulations. Typically, metal-organic formulations for MOCVD comprise a metal alkyl, a metal-alkoxide, a beta-diketonate, combinations thereof, as well as many other precursor formulations. In one embodiment, a multi-metal polyalkoxide may be used. MOD formulations can be formed by reacting a carboxylic acid, such as 2-ethylhexanoic acid, with a metal or metal compound in a solvent. Solvents which may be employed in any of the above formulations include methyl ethyl ketone, isopropanol, methanol, tetrahydrofuran, xylene, n-butyl acetate, hexamethyl-disilazane (HMDS), octane, 2-methoxyethanol, and ethanol. An initiator, such as methyl ethyl ketone (MEK), may be added. A more complete list of solvents and initiators, as well as specific examples of metal compounds, are included in U.S. Pat. No. 6,056,994, issued May 2, 2000 to Paz de Araujo et al., entitled “Liquid Deposition Methods Of Fabricating Layered Superlattice Materials”, and U.S. Pat. No. 5,614,252, issued Mar. 25, 1997 to McMillan et al., entitled “Method Of Fabricating Barium Strontium Titanate”, which patents are hereby incorporated by reference to the same extent as if fully set forth herein.

A “gasified” precursor as used herein refers to gaseous forms of all the constituents previously contained in a liquid precursor, for example, vaporized reagents and vaporized solvent. The term “gasified precursor” refers to the gasified form of a single precursor or the gas phase mixture of a plurality of precursors. The terms “reactant” and “reactant gas” in this application will generally refer to a gas phase mixture containing reagents involved in the deposition reactions occurring at the substrate plate in the deposition reactor, although the mixture logically includes other chemical species, such as vaporized solvent and unreactive carrier gas.

Preferably, a liquid precursor contains a multi-metal polyalkoxide reagent, particularly to reduce the total number of liquid precursors to be misted, mixed, and gasified. Nevertheless, the use of single-metal polyalkoxide precursors is fully consistent with the method and apparatus of the invention. All polyalkoxides are also “alkoxides”. Multi-metal polyalkoxides are included within the terms “metal alkoxides” and “metal polyalkoxides”. The terms “polyalkoxide”, “metal polyalkoxide”, and “multi-metal polyalkoxide” are, therefore, used somewhat interchangeably in this application, but the meaning in a particular context is clear.

The term “premature decomposition” in this application refers to any decomposition of the reagents that does not occur at the heated substrate. Premature decomposition includes, therefore, chemical decomposition of reagents in various stages of the vaporizer and in a deposition reactor itself, if it is not at the heated substrate. Since it is known from the art of thermodynamics and chemical reaction kinetics that some premature decomposition will almost certainly inevitably occur to a slight extent even under optimum operating conditions, it is desirable to prevent “substantial premature decomposition”. Substantial premature decomposition occurs if premature decomposition causes the formation of particles of solid material on the substrate, in place of a continuous, uniform thin film of solid material. Substantial premature decomposition also occurs if premature decomposition causes fouling of the CVD apparatus that necessitates shutting down and cleaning the apparatus more frequently than once for every 100 wafers processed.

Herein, a “conduit” is a tube, pipe, or other apparatus for containing fluid flow. A conduit may contain liquid, mist, or gas flow. Herein, a “thermal barrier” is an obstacle to heat transfer between different portions of a vaporizer. A “thermal insulator” is a portion of a thermal barrier preferably including a thermally insulating solid material, although gaseous or liquid insulators may be employed. A thermal barrier may include an air gap.

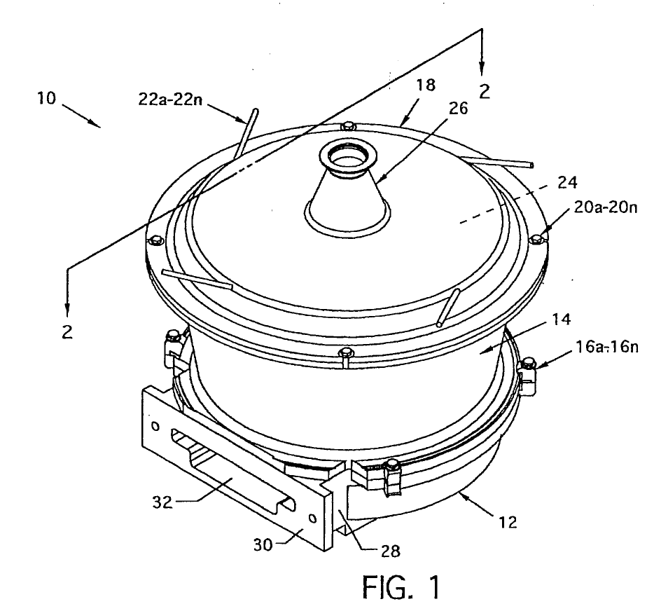

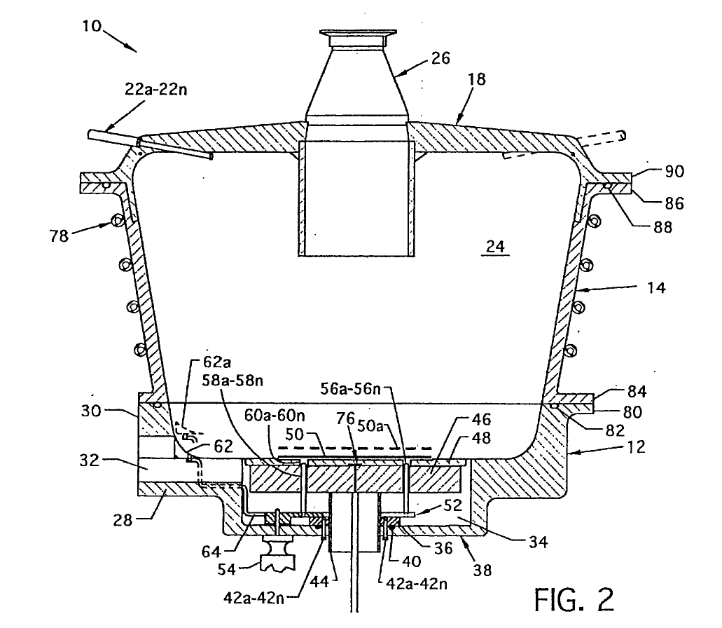

FIG. 1 is a perspective view of a vortex-based CVD (chemical vapor deposition) reactor, also referred to as the CVD reactor 10. Components illustrated in FIG. 1 include a circular reactor base 12, a circular sidewall 14 located above and fitted to and secured to the reactor base 12 by a plurality of clamps 16a-16n, a circular reactor top 18 located above and fitted to and secured to the reactor sidewall 14 by a plurality of hardware assemblies 20a-20n, a plurality of injector tubes 22a-22n tangentially secured to and extending through the reactor top 18 and communicating with the reactor interior 24 (FIG. 2), an exhaust port 26 centrally located at the reactor top 18 in communication with the reactor interior 24, a rectangular reactor base extension 28 extending outwardly from the reactor base 12 having a flange 30, and a robotic arm access port 32 located central to the rectangular reactor base extension 28 in communication with the reactor interior 24.

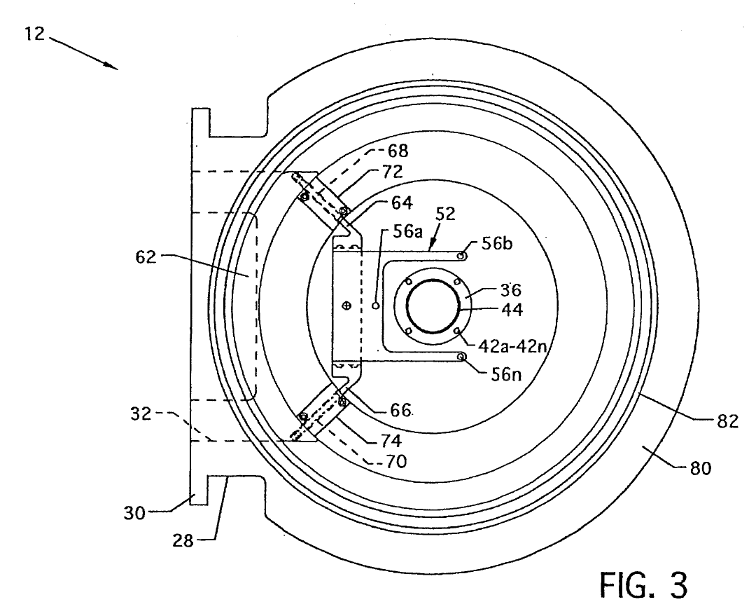

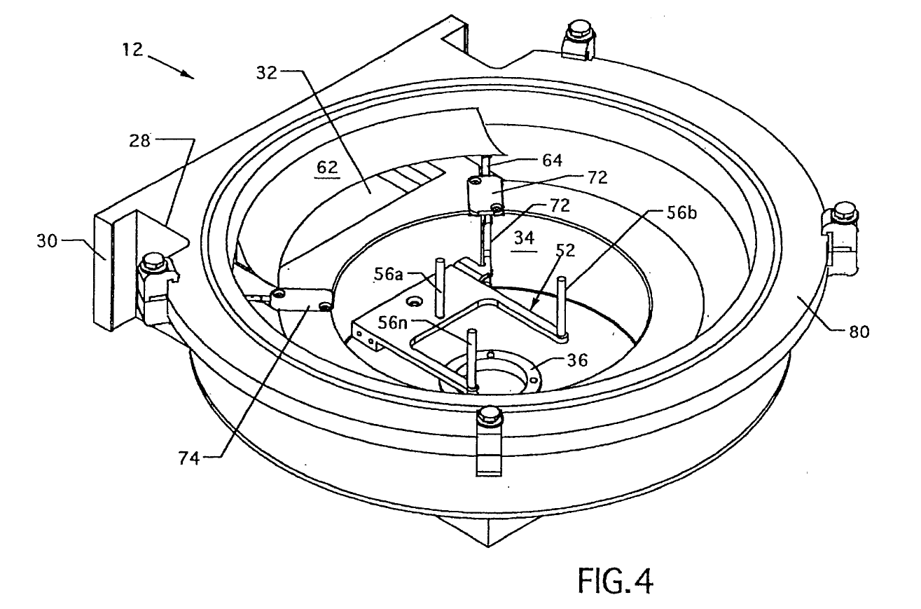

FIG. 2 is a cross-section view of the vortex-based CVD reactor 10 along line 2-2 of FIG. 1, where all numerals mentioned previously correspond to those elements previously described. Illustrated in particular are the components located in or adjacent to cavity 34 located in reactor base 12. Cavity 34 houses a variety of components, most of which are also shown in FIGS. 3 and 4, as now described. An attachment ring 36 seals against the lower planar region 38 of the reactor base 12 by the use of an O-ring 40 and a plurality of machine screws 42a-42n. A connecting support collar 44 extends vertically through the lower planar region 38 of the reactor base 12 and through the attachment ring 36 to support a resistance heated chuck 46. A removable densified carbon susceptor 48 aligns in intimate contact with the resistance heated chuck 46 and uniformly transfers heat to a wafer substrate 50 which intimately contacts the densified carbon susceptor 48. A lift yoke 52, which is actuated vertically by an air cylinder lift arm 54, aligns with sufficient clearance about the connecting support collar 44. A plurality of upwardly directed ceramic lift pins 56a-56n secure to the lift yoke 52 and extend freely through a plurality of mutually aligned body holes 58a-58n and 60a-60n in the heated chuck 46 and the densified carbon susceptor 48, respectively. The tops of the ceramic lift pins 56a-56n can extend beyond the upper surface of the densified carbon susceptor 48 when the lift yoke 52 is actuated to its uppermost travel.

Preferably, lift pins 56a-56n, which are preferably made of a ceramic material, support wafer substrate 50 for either processing or robotic handling. Lift yoke 52 is shown in its lowermost position whereby wafer substrate 50 is allowed to intimately contact susceptor 48, which is preferably made of densified carbon, for processing. Also attached to lift yoke 52 is positionable shutter 62, also shown in FIGS. 3 and 4. Shutter 62 is preferably shaped to conform to the contour of the lower region of reactor base 12 to assist in providing a uniformly smooth shaped reactor interior 24. Multiply angled brackets 64 and 66 suitably secure to the lift yoke 52 and are located in channels 68 and 70 (FIG. 3) in the lower region of the reactor base 12 to attach to and to provide support for positionable shutter 62. Plates 72 and 74 secure over and about channels 68 and 70 to limit upward movement of the multiply-angled brackets 64 and 66 and correspondingly to limit upward movement of shutter 62 in the open mode. For robotic handling, lift yoke 52 is moved upward to position lift pins 56a-56n above the upper surface of the susceptor 48, thereby moving substrate 50 to raised position 50a. Simultaneously, shutter 62 is moved to raised position 62a to allow access to reactor interior 24 by robotic means entering through robotic arm access port 32. For insertion of a wafer substrate, lift yoke 52, including shutter 62 and lift pins 56a-56n, is positioned to its full upward position whereby robotic handling equipment deposits a wafer substrate upon the extended ceramic lift pins 56a-56n. Lift yoke 52 is then lowered to deposit the wafer substrate on susceptor 48 and to close the shutter 62.

Preferably, thermocouple 76 is located in chuck 46, which is preferably heated, to sample and control temperature of chuck 46 and susceptor 48 during the deposition process. Heater 78, which is preferably a resistance heater, surrounds the reactor sidewall 14. Also shown is flange 80 at the upper edge of reactor base 12, which, with an O-ring 82, seals against a lower flange 84 of reactor sidewall 14. Upper flange 86 along with an O-ring 88 seals against a flange 90 located on the reactor top 18.

FIG. 3 is a top view of the reactor base 12, where all numerals correspond to those elements previously described. Illustrated in particular is the relationship of the lift yoke 52 and the attached shutter 62 to reactor base 12, as previously described.

FIG. 4 is a perspective view of the reactor base 12, where all numerals correspond to those elements previously described. The lift yoke 52 is shown positioned upwardly by the air cylinder lift arm 54 to accept placement of substrate 50 such as by robotic handling equipment. Positioning of the lift yoke 52 upwardly also positions the attached shutter 62 by the multiply-angled brackets 64 and 66 (not shown) so that robotic equipment may access the interior of the CVD reactor 10 through the robotic arm access port 32 to place or retrieve a wafer substrate 50.

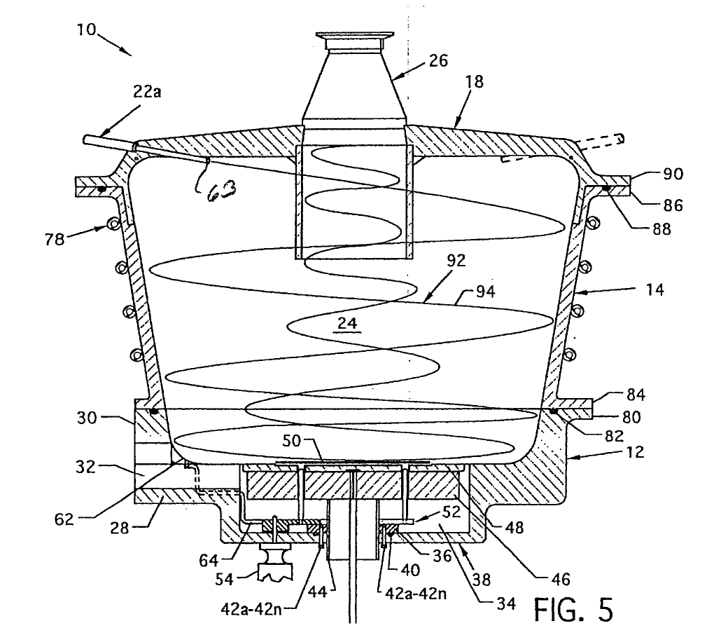

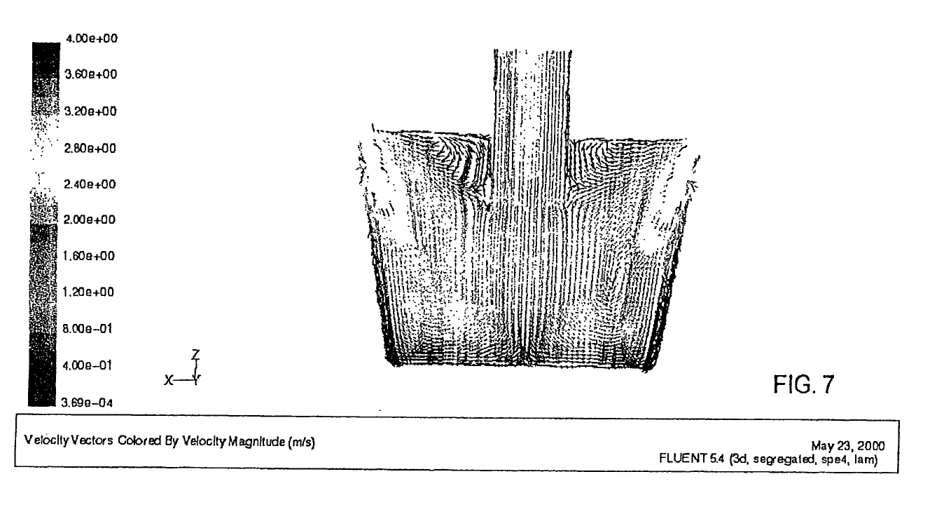

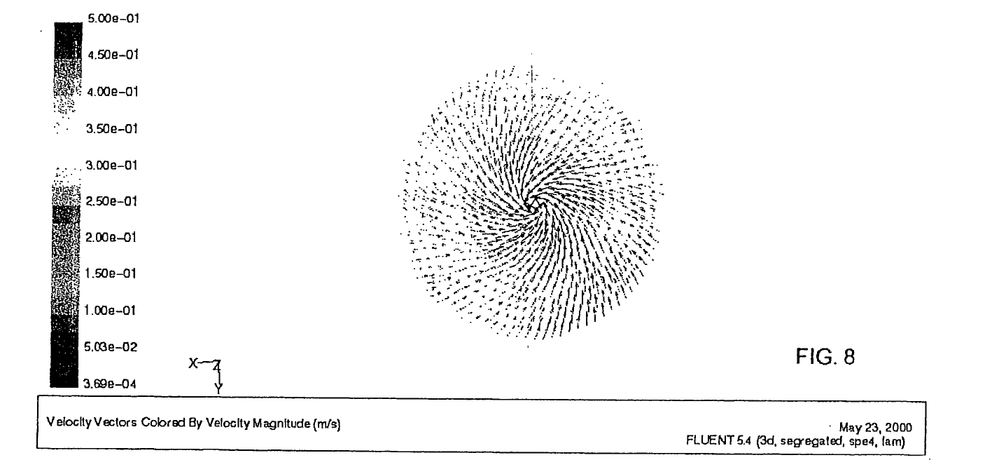

The mode of operation is described in the following. FIG. 5 is a cross-section view of the vortex-based CVD reactor 10 showing a spinning gas field 92 within the reactor interior 24, where all numerals mentioned previously correspond to those elements previously described. Chemical vapors are introduced into the reactor interior 24 simultaneously under sufficient pressure and at suitable temperature through the injector tubes 22a-22n. Preferably, chemical vapors 94 emanate from injector tubes 22a-22n and produce spinning gas fields. For purposes of brevity and clarity, only the spinning gas field 92 produced by and emanating from the injector tube 22a is shown, it being understood that multiple complementary spinning gas fields are preferably produced by and emanate from the remaining injector tubes 22b-22n in a similar fashion. Preferably, the injector tubes 22a-22n are oriented to direct the spinning gas field(s) 92 containing chemical vapors 94 tangentially with respect to the interior walls of the reactor sidewall 14. The rotating gas field moves downward due to the reduced diameter of the reactor (i.e., lower pressure area). The downward spiraling gas hits the lower surface and substrate and is subject to drag. Loss of velocity from drag causes the gas to flow inward and upward to where the pressure is lower. Therefore, the gas spirals upward and out of the reactor exhaust. Conservation of angular momentum maintains continuity of spiral direction and low turbulence. See FIG. 7 (side view) and FIG. 8 (top view at substrate plane).

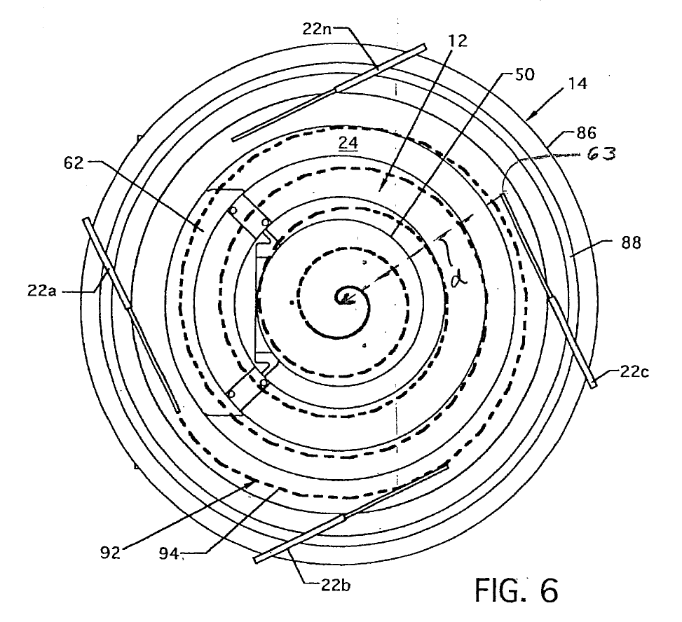

FIG. 6 is a top view of the vortex-based CVD reactor 10 where the reactor top 18 is not shown for purposes of brevity and clarity, but the injector tubes 22a-22n are shown poised above the reactor interior 24 of the CVD reactor 10. As in FIG. 5, and for purposes of brevity and clarity, only the spinning gas field 92 produced by and emanating from the one injector tube 22a is shown, it being understood that multiple complementary spinning gas fields are produced by and emanate from the remaining injector tubes 22b-22n in a similar fashion. All numerals correspond to those elements previously described. As shown in FIG. 6, the gas spirals inward having a component of motion that is in the circular direction and another component in the direction d from the inlet 63 end of injector tube 22c to the exhaust port 26 (FIG. 5). There is also a component of motion in the vertical direction in FIG. 5. Likewise the gas from each of the other inlets have three components of motion.

FIG. 7 illustrates a fluidic simulation of the proposed vortex CVD reactor. FIG. 8 illustrates a simulation showing gas motion at the plane of the substrate where the gas is spiraling with little turbulence. A mathematical discussion is present in Schlicting-Boundary Layer Theory (hereinafter “Schlicting”), relating to a rotating gas field upon a flat surface. Schlicting discusses uniform boundary layers and is related to the simulation shown in FIG. 8. Schlicting indicates that the boundary layer of gas is proportional to the square root of (V/W), where V is the viscosity and W is the rotational velocity (also known as angular frequency and angular velocity). In the embodiment of FIGS. 1-6, the boundary layer thickness generally does not vary with radial position within reactor 10.

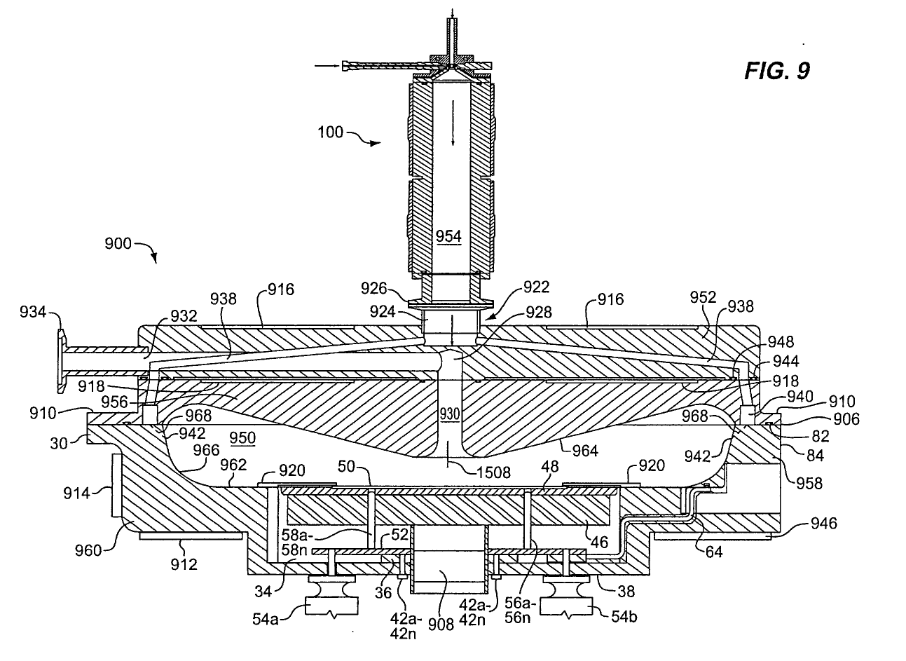

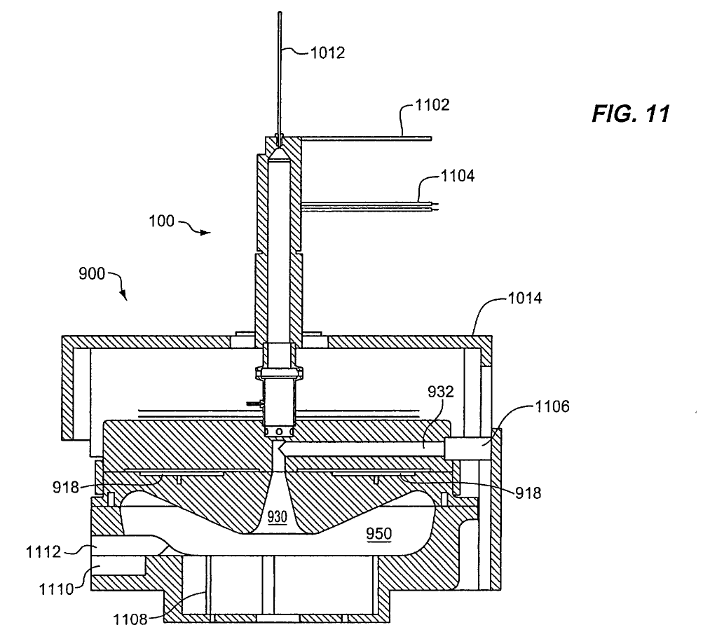

FIG. 9 is a side sectional view of a vaporizer 100 coupled to a reactor 900. Most of the differences between reactor 900 and reactor 10 reside above break line 906, separating reactor top 952 and reactor base 958. The differences between reactor base 958 and reactor base 12 of reactor 10 are discussed first. Shutter 908 is shown below heated chuck 46. Shutter 908 preferably cooperates with curved shutter 1112 (FIG. 11) to provide an opening for robotic access to substrate 50, when appropriate.

One preferred heater for use in thermally controlling reactor 900 is a mica heater. However, in the following, where heaters are discussed, it will be appreciated that a variety of different types of heaters may be employed, which may or may not be in physical contact with reactor 900 surfaces. Moreover, other forms of thermal control may be substituted for the heaters. For instance, cooling mechanisms may be substituted for one or more heaters in alternative embodiments of reactor 900 in which temperatures of selected portions of reactor 900 are sought to be cooled for selected processes. In this embodiment, heater 946 is coupled to reactor base 958. Heater 912 is preferably connected to a downward-facing surface of reactor base extension 28. Heater 914 is preferably connected to an outside vertical wall of reactor base extension 28.

Attention is now directed to reactor top 952. Vaporizer 100 is shown at the top of FIG. 9. Because vaporizer 100 is discussed in detail in a related application which is incorporated herein, the details thereof are not discussed in this section. Vaporizer 100 preferably connects to reactor 900 at reactor connector interface 926. The remainder of the discussion of FIG. 9 concerns three main groupings of parts: gas inlet system 922, reactor chamber 950, and exhaust port 928.

Gas inlet system 922 preferably includes reactor inlet 924, tubes 938, conduit 940, channels 968, and inlets 942 at the inside (chamber) ends of channels 968. Exhaust outlet 928 preferably includes exhaust port 930, exhaust tube 932, and exhaust tube flange 934. In this embodiment, a plurality of tubes 938 are coupled to reactor inlet 924 and direct gas to conduit 940 which is preferably arranged circumferentially about reactor chamber 950. Although only one conduit is shown in FIG. 9, two or more such conduits could be employed within reactor 900. In this embodiment, six tubes 938 are employed to direct gas to conduit 940. However, fewer or more than six tubes may be employed.

In this embodiment, eighteen channels 968, preferably equally spaced about the circumference of reactor chamber 950, direct gas from conduit 940 through inlets 942 into reactor chamber 950. It will be appreciated that fewer or more than eighteen channels 968 and inlets 942 may be employed in reactor 900. Precursor gas 954 preferably flows out of inlets 942, over substrate 50 and substrate guard ring 920, and out through exhaust port 930. Preferably, the vertical distance between the upper surface of substrate 50 and inlet 942 is 10 cm (centimeters) or less, more preferably 5 cm or less, and still more preferably 2.5 cm or less.

In this embodiment, heater 916, which is preferably a mica heater, is circumferentially arranged about the upper surface of reactor top 952. Preferably, another circumferentially configured heater 918 is located above reactor chamber 950 and below exhaust tube 932, at the upper part of reactor mid-portion 956. O-rings 944 and 948 are preferably located between reactor top 928 and reactor mid-portion 956.

Reactor chamber 950 houses substrate 50 and supporting hardware, and provides a structure conducive to desired gas flow characteristics over substrate 50. Reactor chamber 950 includes chamber bottom 962, chamber top 964, and chamber sidewalls 966. It is generally desirable to have gas flow velocity increase with increasing proximity to the center 1508 of reactor chamber 950. The conservation of angular momentum, in combination with the inherent decrease in radial position of flow with progress toward center 1508, provides a first factor of velocity increase with diminishing distance from center 1508. The downward slope of chamber top 964 toward the center 1508 preferably provides a second factor of gas velocity increase with movement toward center 1508. In FIG. 9, a straight-line decrease in chamber height with decreasing distance from center 1508 is shown. However, it will be appreciated that both chamber bottom 962 and chamber top 964 may assume a wide range of shapes. Moreover, a wide range of mathematical relationships, linear and non-linear, may be incorporated into a function relating reactor chamber 950 height to radial position (distance from center 1508). In this embodiment, chamber top 964 is slanted with respect to the horizontal by 14 degrees.

In this embodiment, exhaust port 930 is substantially centered with respect to reactor chamber 950 and is a vertical, or substantially vertical, hollow region above center 1508 of reactor chamber 950. Exhaust port 930 preferably connects to horizontal exhaust tube 932, which tube 932 preferably terminates at exhaust tube flange 934.

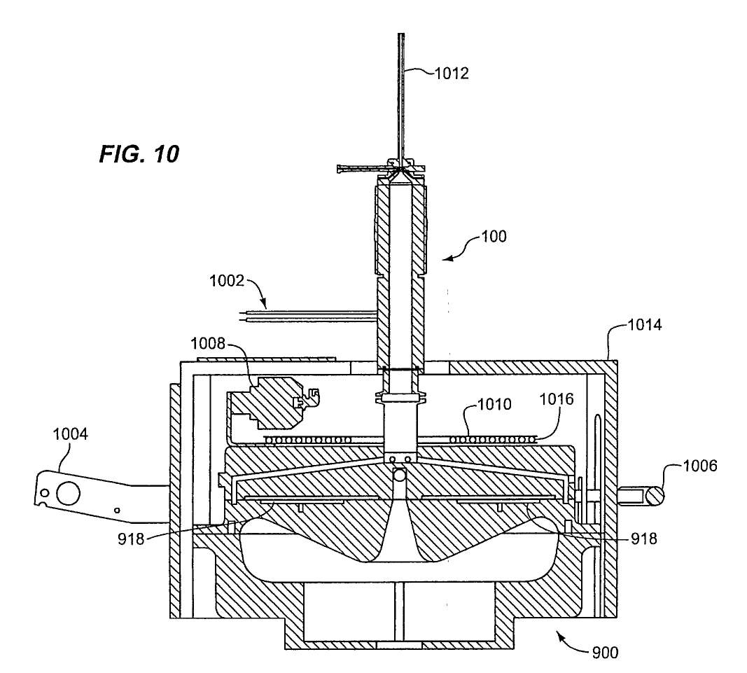

FIG. 10 is a side sectional view of vaporizer 100 and reactor 900 of FIG. 9 showing reactor housing 1014. FIG. 10 includes some miscellaneous parts not discussed in connection with FIG. 9. Those parts previously discussed in connection with FIGS. 2-6 and/or FIG. 9 are not discussed in this section.

As in FIG. 9, vaporizer 100 connects to reactor 900. Electrical leads 1002 lead to one of the heaters for vaporizer 100. Reactor housing 1014 surrounds reactor 900. Hinge arm 1004 is connected to the left side (in the view of FIG. 10) of reactor housing 1014. Hinge arm 1004 preferably allows reactor housing 1014 to pivot into a position which leaves reactor 900 unobstructed. Housing handle 1006 is shown connected to the right side (in the view of FIG. 10) of reactor housing 1014. Housing handle 1006 is preferably used to move or pivot reactor housing 1014 into a desired position. In this embodiment, tubing plate 1010 is located above a spirally wound aluminum tubing 1016, which tubing is located above heater 916. Preferably, tubing 1016 is coupled to gas valve 1008. The output of gas valve 1008 is preferably directed to the top (in the view of FIG. 10) of carrier gas tube 1012 of vaporizer 100.

FIG. 11 is a side sectional view of vaporizer 100 and reactor 900 of FIG. 9 showing primary exhaust connection 1106. FIG. 10 includes some miscellaneous parts not discussed in connection with FIG. 9. Those parts previously discussed in connection with FIGS. 2-6, 9, and 10 are not discussed in this section. Liquid conduit 1102 directs fluid toward vaporizer 100. Electrical leads 1104 lead to a heater (not shown) on vaporizer 100.

In this embodiment, exhaust port 930 is located above the center of vaporization chamber 950. Preferably, exhaust port 930 connects to exhaust tube 932, which in turn leads to primary exhaust connection 1106. In this embodiment, guard ring linkage 1108 is located to the left and near the bottom of reactor 900 and is operative to lift and lower substrate guard ring 920 (FIG. 9). Preferably, guard ring linkage 1108 raises guard ring 920 while substrate 50 is being inserted into or removed from reactor chamber 950. Preferably, once substrate 50 is in place within reactor chamber 950, guard ring linkage 1108 operates to lower guard ring 920 to secure and protect substrate 50. Robotic arm access port 1110 is located at the left (in the view of FIG. 11) and near the bottom of reactor 900. Preferably, curved shutter 1112 is located right above access port 1110.

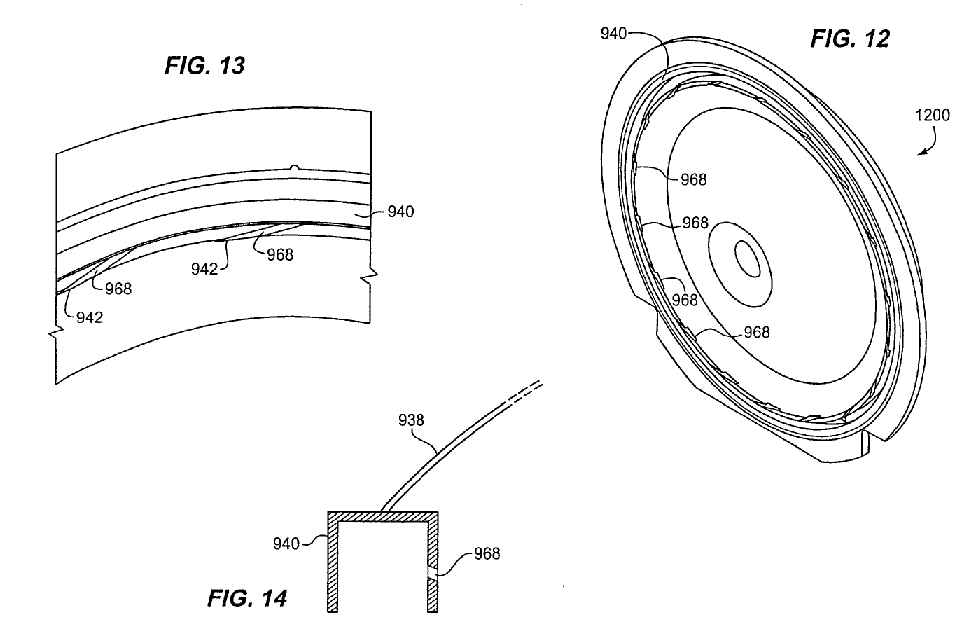

FIG. 12 is a perspective view of a portion of reactor 900 showing a plurality of channels 968 leading out of conduit 940. In this embodiment, eighteen channels 968 lead from conduit 940 into reactor chamber 950. However, fewer or more than eighteen channels 968 may be employed. However many channels 968 are employed, channels 968 are preferably evenly spaced about the circumference of reactor chamber 950, along conduit 940. FIG. 13 is a close-up isometric view of a portion of conduit 940 and of two channels 968 leading out of this portion. Preferably, an inlet 942 is located at the chamber 950 end of each channel 968. It may be seen that the angle between the axis of channels 968 and the axis of conduit 940 is acute. Preferably, the axes of channels 968 are substantially tangential to the direction of the axis of conduit 940. FIG. 14 is a front-end section view of a portion of conduit 940 connected to tube 938 and channel 968. In this embodiment, six tubes 938 are provided, which are preferably equally spaced about the circumference of reactor chamber 950. In alternative embodiments, fewer or more than six tubes 938 may be employed. Moreover, in alternative embodiments, tubes 938 could be non-uniformly distributed about the circumference of chamber 950.

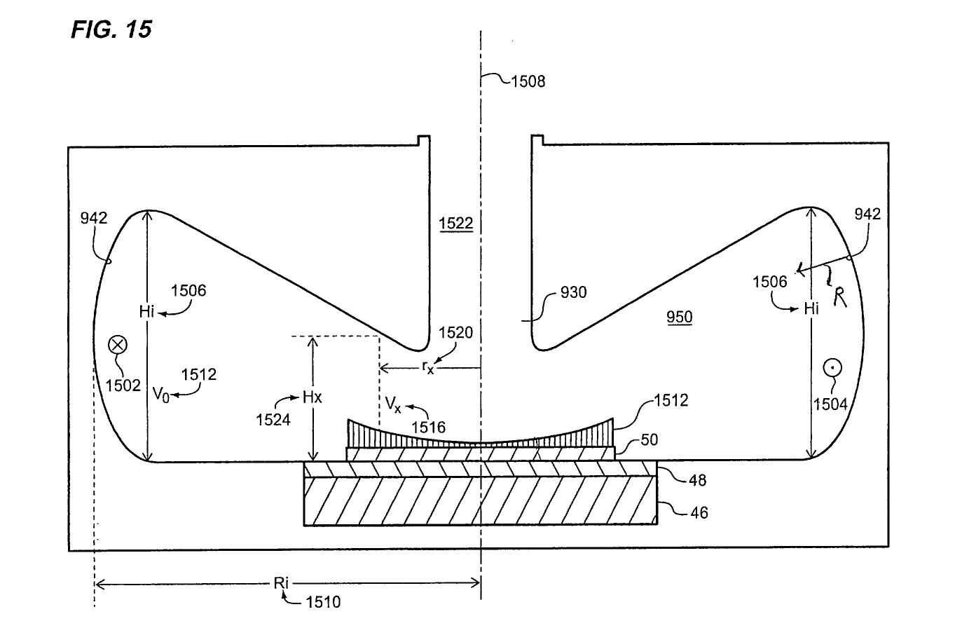

FIG. 15 is an expanded side sectional view of a portion of reactor chamber 950 shown in FIG. 9. Most the apparatus components shown in FIG. 15 are discussed in connection with FIGS. 2-6 and 9-11, and that discussion will therefore not be repeated in this section. In this embodiment, substrate 50 is located above susceptor 48. Gas flow boundary layer 1512 is above substrate 50. The thickness of boundary layer 1512 may be controlled by controlling gas 954 velocity as a function of radial position 1520.

An optional gas heating operation is now discussed with reference to FIGS. 9-11. In this embodiment, a gas heating mechanism is practiced to exploit the availability of heat from reactor 900 to bring carrier gas to a desired temperature after it exits reactor chamber 950. In this embodiment, after gas 954 leaves reactor chamber 950, it is directed to tubing 1016 (FIG. 10), which is preferably sandwiched between tubing plate 1010 and heater 916 (or other heater). At this point, this gas is generally carrier gas, since most reagents have been removed therefrom. After proceeding through tubing 1016, the carrier gas is preferably directed to valve 1008. Valve 1008 preferably controls the transmission of carrier gas toward carrier gas conduit 1012 of vaporizer 100. The carrier gas is preferably brought to a temperature of about 200° C. In this manner, heat which would otherwise dissipate may be beneficially exploited to generate “free” heating for carrier gas directed to conduit 1012.

The operation of the embodiments of the CVD reactors disclosed herein are discussed below with reference to FIGS. 1-15. A discussion of the features of reactor 10 of FIGS. 2-6 and reactor 900 of FIGS. 9-15 is provided. Thereafter, a detailed discussion of the operation of the embodiment of FIGS. 9-15 is provided.

The reactor 900 embodiment of FIG. 9 is considerably shorter than reactor 10 of FIGS. 1-6. One effect of this height reduction for reactor 900 is to allow gas inlet system 922 of reactor 900 to introduce precursor gas 954 at a vertical level much closer to the level of the top surface of substrate 50. This greater vertical proximity between the introduction of gas and substrate 50 preferably increases the gas velocity in the vortex created within the respective chambers.

Reactor 900 provides a modified system for introducing gas into chamber 950 than that used in reactor 10. Reactor 10 of FIG. 5 employs a plurality of tubes to directly inject gas into the interior of reactor 10 to produce a spiral flow. Reactor 900 (FIG. 9) includes gas inlet system 922 to introduce gas to chamber 950. Gas inlet system 922 preferably includes a plurality of tubes 938 which direct gas into a circumferential conduit 940 which operates as a form of gas manifold for precursor gas 954. Precursor gas 954 circulates through conduit 940 and is introduced into reactor chamber 950 through a plurality of channels 968 which lead to inlets 942, which in turn lead into reactor chamber 950. The structure of gas inlet system 922 preferably provides improved gas flow uniformity at the inside perimeter of reactor chamber 950 and better control of the direction of precursor gas 954 upon introduction to reactor chamber 950. Reactor 900 introduces a height which varies with radial position. While the height of the interior of reactor 10 of FIGS. 1-6 is essentially constant, the height of reactor chamber 950 (FIGS. 9-11 and 15) is preferably a function of radial distance 1520 from chamber center 1508 of reactor chamber 950. In the embodiment of FIG. 9, the variation in chamber height is provided exclusively by the sloped internal upper surface of reactor chamber 950, since the bottom surface of reactor chamber 950 is substantially flat. However, in alternative embodiments, the bottom internal surface of reactor chamber 950 could also be shaped to reduce chamber height with diminishing distance from chamber center 1508. In an alternative embodiment, the bottom and upper surfaces could be designed to be symmetric about a horizontal centerline separating these two portions. In still other alternative embodiments, the upper and lower portions could have different chamber-height-varying shapes.

The flow of gas within reactor chamber 950 is considered. The flow of precursor gas 954 from tubes 938 through inlets 942 was discussed earlier, and that discussion, therefore, will not be repeated in this section. Similarly, the flow of depleted precursor gas 954 through tubing 1010 (FIG. 10) and ultimate direction into vaporizer carrier gas conduit 1012 was discussed previously, and that discussion also will not be repeated in this section. This section is directed to discussion of the ambient conditions and the flow conditions of precursor gas 954 in reactor chamber 950 between emission from inlets 942 and exhaust port 930.

With reference to FIG. 15, precursor gas 954 enters reactor chamber 950 at inlets 942, one of which is shown on either side of reactor chamber 950. It is noted that a preferred embodiment of reactor chamber 950 includes eighteen inlets 942. In the embodiment of FIG. 15, on the left side of chamber 950, gas 954 moves perpendicularly to the plane of FIG. 15 and out 1502 of the page. Similarly, on the right side, gas 954 moves perpendicularly to the plane of FIG. 15 and into 1504 the page. Upon being emitted from inlets 942, precursor gas 954 preferably moves with a linear velocity of about 4 meters per second.

In this embodiment, the pressure and temperature conditions within reactor chamber 950 are tightly controlled because of the sensitivities of various precursor reagents. Specifically, the temperature should be high enough to avoid condensation and low enough to avoid premature decomposition. Since many reagents may be included in precursor gas 954, ambient conditions should be selected which avoid condensation and premature decomposition for all such reagents. Preferably, precursor gas 954 is kept at about 200° C. Preferably, the static pressure within chamber 954 is about 1 torr. This low pressure environment preferably enables precursor gas to avoid condensation even at temperatures lower than those used in many existing MOCVD (Metal Organic Chemical Vapor Deposition) reactor environments. Preferably, chamber sidewalls 966 of reactor chamber 950 are kept at about 190° C. In this embodiment, substrate 50 is kept at a temperature between 320° C. and 360° C., and more preferably at about 340° C. The relatively low temperature of substrate 50 preferably prevents the decomposition and particulate matter precipitation from precursor gas 954 experienced in some existing reactors using higher substrate temperatures.

Preferably, the stationary condition of heated chuck 46 simplifies the design of reactor 900 by removing the need for equipment for rotating chuck 46. Separately, in existing systems, the rotation of chuck 46 tends to complicate the routing of thermocouple cabling or other instrumentation leads used for substrate temperature measurement. However, the stationary condition of chuck 46 in reactor 900 preferably makes substrate temperature measurement less cumbersome by allowing instrumentation leads to be undisturbed by the rotation of chuck 46 and substrate 50. A substrate holder comprising chuck 46 and susceptor 48 holds a substrate 50.

In this embodiment, while proceeding from inlets 942 toward chamber center 1508, precursor gas is accelerated by several factors. The first factor is the conservation of angular momentum which, for a chamber of constant height, requires that the product of V·R remain constant, where V is velocity and R is the radial position of the flow where V is being measured. In chambers having a non-varying height, like that of reactor 10, this approach helped provide a constant boundary layer thickness of flow over substrate 50. This approach helped replicate the effect of the rotation of a substrate under a stationary showerhead, which effect was present in prior art showerhead-based gas dispensing systems. However, it was found that, in a spiral gas system like that shown in FIGS. 2-6, the concentration of reagents in the precursor gas would become progressively more depleted with increased travel through the interior of reactor 10. Accordingly, reagent concentration was lower near the center of reactor 10 than at the perimeter. The combination of lower reagent levels near the center of reactor 10 and substantially uniform boundary layer flow thickness over substrate 50 led to lower film growth rate near the center of substrate 50 in reactor 10. Specifically, in some processes conducted in constant height reactors, film growth rate at the center of substrate 50 was only 20% of that achieved at the edges of substrate 50. The growth rate achieved at the substrate 50 center was about 10 angstroms per minute.

Accordingly, a mechanism to compensate for reagent depletion occurring with movement toward the reactor center was pursued. It was found that controlling the flow characteristics of precursor gas 954, including, in particular, the velocity, and boundary layer thickness 1512 of gas flow over substrate 50 was helpful in this effort. One beneficial approach involves varying reactor chamber height as a function of radial position within reactor chamber 950 to add an additional factor of velocity increase with diminishing distance from reactor center 1508. Higher velocity flow preferably decreases the boundary layer 1512 thickness of flow over substrate 50, which in turn increases the diffusion of reagents through boundary layer 1512 to substrate 50. Preferably, the increased rate of diffusion of reagents appropriately compensates for the reduction in reagent concentration to generate a substantially uniform rate of film growth on the surface of substrate 50. Since reagent depletion increases with decreasing radial distance 1520, compensating for this effect may be accomplished by appropriately increasing gas 954 flow velocity with decreasing radial distance 1520.

In general, decreasing the height 1524 of reactor chamber 950 as a function of radial position 1520 causes gas 954 flow velocity 1516 to increase inversely proportionally to the decrease in height (in addition to any other factors affecting flow velocity 1516). Height 1524 may be varied with respect to radial position, Rx 1520, employing a wide range of linear and non-linear functions, including exponential functions. In the embodiment of FIGS. 9-11 and 15, chamber height 1524 varies linearly with radial position 1520. However, it will be appreciated by those skilled in the art that designs incorporating other mathematical relationships between chamber height and radial position may be employed.

Directing attention to FIG. 15, it may be seen that the value of precursor gas 954 velocity at any arbitrary radial position Rx may be given by the following equation:

Vx=Vₒ·(Hi/Hx)·(Ri/Rx) (1)

where Vx 1516 is gas velocity, Vₒ 1512 is initial gas velocity, Hi 1506 is the height of reactor chamber 950 where gas 954 is introduced into reactor chamber 950, Hx 1524 is the height of reactor chamber 950 at radial position Rx 1520, Ri 1510 is the radius of reactor chamber 950, and Rx 1520, as indicated, is the radial position at which the gas velocity Vx 1516 is measured. The relationship between chamber height 1524 and radial position 1520 may be adjusted by modifying the shape of chamber bottom 962 and/or chamber top 964 to effect a desired rate of velocity increase based on the reagent depletion incurred by precursor gas 954. The variables relevant to determining the desired shape of reactor chamber 950 may be determined by experimentation and/or analysis. These variables include, but are not limited to, the rate of reagent concentration as a function of radial position 1520, the boundary layer 1512 thickness, variation of temperature and/or pressure with radial position 1520, and the rate of film growth, as a function of location, over substrate 50.

Thus, the velocity of precursor gas 954 accelerates according to equation (1) above as it proceeds toward chamber center 1508. Preferably, the thickness of boundary layer 1512 decreases with decreasing magnitude of Hx/Hi, thereby enabling the diffusion rate over substrate 50 to increase with increasing Hi/Hx. Preferably, the rate of increase in the diffusion rate from precursor gas 954 to substrate 50, as a function of diminishing Rx 1520, substantially equals the rate of decline in reagent concentration over the same Rx 1520 range, thereby achieving the desired compensation for reagent concentration variation with radial position. Preferably, achieving this desired compensation causes the rate of film growth to be substantially uniform over the surface of substrate 50. Experimentation employing deposition processes within reactor chamber 950 indicates that the film growth rate at the center of substrate 50 was 97% of that experienced at the edges of substrate 50—a vast improvement over the 20% ratio experienced employing a constant-height reactor. Moreover, the growth rate achieved at the center of substrate 50 was about 100 angstroms per minute, representing a ten-fold increase over the growth rate employing a constant-height reactor chamber.

In summary, a feature of the invention is that the reactor volume available to the precursor gas as the gas moves from inlet 942 to exhaust port 930 is reduced by the invention. That is, as the gas moves in the direction R from inlet 942 to exhaust port 930, the reactor volume per unit distance along this direction decreases; i.e., for each cm of distance along the direction R, the volume that includes that cm will be smaller as the gas moves from the inlet 942 to exhaust port 930. In the preferred embodiment of the invention, the direction R is substantially radially inward. However, the invention contemplates that the direction R could be substantially radially outward or in any other direction. The important thing is that as gas is removed from the chamber by deposition, the volume available to the gas is reduced so that the deposition rate per unit area of the substrate will stay essentially the same.

Preferably, after reaching chamber center 1508, or a region substantially proximate thereto, precursor gas 954 proceeds up through exhaust port 930, and along exhaust tube 932.

There have been described what are, at present, considered to be the preferred embodiments of the invention. It will be understood that the invention can be embodied in other specific forms without departing from its spirit or essential characteristics. For instance, each of the inventive features mentioned above may be combined with one or more of the other inventive features. That is, while all possible combinations of the inventive features have not been specifically described, so as the disclosure does not become unreasonably long, it should be understood that many other combinations of the features can be made. The present embodiments are, therefore, to be considered as illustrative and not restrictive. The scope of the invention is indicated by the appended claims.

1. A chemical vapor deposition method comprising:
providing a reactor chamber including a substrate defining a substrate plane;
moving a precursor gas through said chamber in a direction from a gas inlet to an exhaust port and in a circular motion about an axis substantially perpendicular to said substrate plane while reducing the reactor volume per unit distance available to said precursor gas as said precursor gas moves in said direction; and
reacting said vapor to deposit a solid thin film on the surface of said substrate.

2. The method of claim 1 wherein said moving comprises providing spiral motion.

3. The method of claim 1 wherein said moving comprises increasing a velocity of said precursor gas with increasing proximity of said precursor gas to a center of said reactor chamber.

4. The method of claim 1 wherein said moving comprises controlling flow characteristics of said moved precursor gas to compensate for depletion of reagents within said moved precursor gas.

5. The method of claim 1 wherein said moving comprises controlling flow characteristics of said moved precursor gas to substantially equalize said film thickness across said substrate surface.

6. The method of claim 1 wherein said moving comprises decreasing a boundary layer thickness of gas precursor flow over said substrate surface with increasing proximity to a center of said reactor chamber.

7. The method of claim 1 wherein said moving comprises increasing a diffusion rate of reagents from said precursor gas to said substrate surface with increasing proximity to a center of said reactor chamber.

8. The method of claim 1 wherein said providing a reactor chamber comprises providing a substantially circular reactor chamber and said direction is substantially radially inward.

9. The method of claim 1 wherein said reducing comprises reducing a height of said reactor chamber with increasing proximity to the center of said reactor chamber.

10. The method of claim 1 further comprising maintaining said substrate substantially stationary.

11. The method of claim 1 further comprising maintaining a temperature of said reactor chamber below a decomposition temperature of said precursor gas.

12. The method of claim 11 wherein said maintaining comprises maintaining a temperature of sidewalls of said reactor chamber at substantially 200° C.

13. The method of claim 11 wherein said maintaining comprises maintaining a temperature of said precursor gas at substantially 200° C.

14. The method of claim 1 further comprising maintaining a pressure within said reactor chamber below 10 Torr (1333 Newtons per square meter).

15. The method of claim 1 further comprising maintaining a pressure within said reactor chamber at substantially 1 Torr (133.3 Newtons per square meter).

16. The method of claim 1 further comprising maintaining a temperature of said substrate between 320° C. and 360° C.

17. The method of claim 1 further comprising maintaining a temperature of said substrate at substantially 340° C.

18. The method of claim 1 wherein said moving comprises causing said precursor gas to enter said reactor chamber 10 cm or less above the level of said substrate plane.

19. The method of claim 1 wherein said moving comprises causing said precursor gas to enter said reactor chamber 5 cm or less above the level of said substrate plane.

20. The method of claim 1 wherein said moving comprises causing said precursor gas to enter said reactor chamber 2.5 cm or less above the level of said substrate plane.

21. A chemical vapor deposition (CVD) reactor comprising:
a reactor chamber;
a substrate holder located within said reactor chamber and defining a substrate plane;
a gas inlet system including a gas inlet; and
a gas exhaust port;
wherein said reactor chamber is shaped such that the reactor volume per unit distance decreases in a direction from said gas inlet to said gas exhaust port.

22. A CVD reactor as in claim 21 wherein said reactor chamber includes a circular wall and said gas inlet system comprises a gas inlet directed substantially tangential to said circular wall.

23. A CVD reactor as in claim 21 wherein said reactor chamber is substantially circular and said direction is radially inward.

24. A CVD reactor as in claim 21 wherein said reactor includes a top wall, and wherein a height of said reactor chamber top wall above said substrate holder increases with increasing distance from a center of said chamber.

25. A CVD reactor as in claim 24 wherein said height of said chamber top wall above said substrate holder varies substantially linearly with a distance from said center of said chamber.

26. A CVD reactor as in claim 21 wherein said reactor includes a top wall, and wherein a height of said reactor chamber top wall above said substrate is a function of a reagent depletion rate in said chamber.

27. A CVD reactor as in claim 21 wherein said reactor includes a top wall, and wherein a height of said reactor chamber top wall above said substrate varies with radial position to compensate for a rate of reagent depletion during gas flow through said chamber.

28. A CVD reactor as in claim 21 wherein said reactor includes a top wall, and said shape of said chamber is designed to provide substantially uniform film growth rate on a substrate located on said substrate holder.

29. A CVD reactor as in claim 21 wherein said substrate holder is substantially fixed within said reactor so that it is substantially stationary.

30. A CVD reactor as in claim 21 wherein said substrate holder comprises a heater.

31. A CVD reactor as in claim 21 wherein said gas inlet system comprises a plurality of tubes arranged to direct gas into a conduit.

32. A CVD reactor as in claim 21 wherein said gas inlet system comprises a conduit arranged circumferentially about said reactor chamber.

33. A CVD reactor as in claim 21 wherein said gas inlet system comprises a plurality of channels through said reactor chamber.

34. A CVD reactor as in claim 33 wherein said channels are oriented substantially tangentially to a sidewall of said reactor chamber.

35. A CVD reactor as in claim 21 wherein said inlet is at a periphery of said reactor chamber.

36. A CVD reactor as in claim 21 wherein said gas inlet system, said reactor chamber, and said gas exhaust port cooperate to provide spiral gas flow from an internal perimeter of said chamber, over said substrate holder, to said gas exhaust port.

37. A CVD reactor as in claim 21 wherein said exhaust port is substantially centrally located in said reactor.

38. A CVD reactor as in claim 21 wherein said chamber includes a top wall and at the periphery of said chamber said top wall is 10 cm or less above the level of said substrate plane and near said exhaust port, and said top wall is 5 cm or less above the level of said substrate plane.

39. A CVD reactor as in claim 21 wherein said chamber includes a top wall and at the periphery of said chamber said top wall is 5 cm or less above the level of said substrate plane and near said exhaust port, and said top wall is 2.5 cm or less above the level of said substrate plane.
